(19) United States
(12) Patent Application Publication
(10) Pub. No.: US 2025/0098500 A1
(43) Pub. Date: Mar. 20, 2025

(54) DISPLAY SUBSTRATE, MANUFACTURING METHOD THEREOF, AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Dongyu Gao, Beijing (CN); Zhenye Wei, Beijing (CN); Cheng Zeng, Beijing (CN); Li Chen, Beijing (CN); Jinglu Bai, Beijing (CN); Yunhao Wang, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/572,960

(22) PCT Filed: Sep. 28, 2022
(86) PCT No.: PCT/CN2022/122169

§ 371 Date: Dec. 21, 2023

(51) Int. Cl. H10K 59/80; H10K 59/12; H10K 59/122

(52) U.S. Cl. CPC H10K 59/8792; H10K 59/1201; H10K 59/122; H10K 59/873

(57) ABSTRACT

Display substrate, manufacturing method thereof and display device are provided. The display substrate includes: light-emitting substrate including light-emitting device, switch element and encapsulation layer; color conversion layer including separation bank, color conversion pattern and leveling layer, the separation bank defining first openings corresponding to pixels, including light-transmitting bank and light-shielding bank patterns, the light-transmitting bank pattern has grooves in which the light-shielding bank pattern is filled, the color conversion pattern is disposed in the first openings, the leveling layer is at least partially filled in the first opening to fill first step for forming flat surface away from the substrate; a color filtering layer including light-shielding and color filtering patterns, the light-shielding pattern defining second openings corresponding to the first openings in which the color filtering pattern is disposed in. The display substrate, manufacturing method thereof and the display device can improve the displaying quality.

### TECHNICAL FIELD

The present disclosure relates to the technical field of display, and in particular, to a display substrate, a manufacturing method thereof, and a display device.

### BACKGROUND

The QD-OLED (quantum dot panel) is considered as the next generation displaying solution due to its good performance on color gamut and good color displaying. In the QD-OLED, blue OLEDs (Organic Light Emitting Diode) are used as a backlight source to excite photochromic QD (quantum dot) particles to obtain monochromatic red light and green light.

### SUMMARY

Embodiments of the present disclosure provide a display substrate and a manufacturing method thereof, and a display device, which can improve the quality of a display product.

The technical solution provided by the embodiments of the present disclosure is as follows.

An embodiment of the present disclosure provides a display substrate, having a plurality of pixels distributed in an array; the display substrate includes:

a light-emitting substrate, including a base substrate, and a plurality of light-emitting devices, a plurality of switch elements and an encapsulation layer arranged on the base substrate, where the switch element is configured to drive the light-emitting device to emit light, the encapsulation layer encapsulates the light-emitting device, and at least one light-emitting device and at least one switch element are arranged in each pixel correspondingly;

a color conversion layer arranged at a side of the encapsulation layer away from the base substrate, where the color conversion layer includes a separation bank, a color conversion pattern and a leveling layer, the separation bank includes a plurality of first portions extending in a first direction and a plurality of second portions extending in a second direction, the first direction intersects with the second direction and is parallel to the base substrate, the plurality of first portions and the plurality of second portions intersect with each other to define a plurality of first openings corresponding to the plurality of pixels, at least one of the first portion and the second portion includes a light-transmitting bank pattern and a light-shielding bank pattern, the light-transmitting bank pattern is provided with a groove arranged in a direction in which the at least one of the first portion and the second portion extends, the light-shielding bank pattern is filled in the groove, the color conversion pattern is arranged in the first opening, and a first step is between the color conversion pattern and the separation bank in a direction perpendicular to the base substrate, and the leveling layer at least partially fills the first opening to fill the first step and form a flat surface at a side away from the base substrate; and

a color filtering layer, arranged at a side of the color conversion layer away from the base substrate, where the color filtering layer includes a light-shielding pattern and a color filtering pattern, the light-shielding pattern defines a plurality of second openings corresponding to the plurality of first openings, and the color filtering pattern is arranged in the second opening.

Illustratively, the display substrate further includes at least one buffer layer.

The at least one buffer layer is located on the flat surface of the leveling layer, and the color filtering layer is located at a side of the buffer layer away from the color conversion layer; and/or

the at least one buffer layer conformally covers a side of the color conversion pattern and the separation bank away from the base substrate, to form an uneven area formed by the first step, and the leveling layer is located at the side of the buffer layer away from the base substrate and at least fills the uneven area to form the flat surface.

Illustratively, the color conversion pattern includes a quantum dot material or a fluorescent material.

Illustratively, the light-shielding pattern includes a plurality of third portions extending in the first direction and a plurality of fourth portions extending in the second direction, the plurality of third portions and the plurality of fourth portions intersect with each other to define the plurality of second openings.

A maximum width of the third portion in the second direction is greater than or equal to a maximum width of a corresponding first portion in the second direction; a maximum width of the fourth portion in the first direction is greater than or equal to a maximum width of a corresponding second portion in the first direction.

Illustratively, in the direction perpendicular to the base substrate, the light-transmitting bank pattern has a first top face at the side away from the base substrate, and the light-shielding bank pattern has a second top face at the side away from the base substrate; the light-shielding bank pattern and the light-transmitting bank pattern have the same thickness in the direction perpendicular to the base substrate so that the first top face is flush with the second top face.

Illustratively, in the direction perpendicular to the base substrate, the light-transmitting bank pattern has a first bottom face at a side facing the base substrate; the light-transmitting bank pattern comprises two opposite inner side walls in contact with the light-shielding bank pattern.

The two inner side walls incline with respect to the base substrate from the first top face to the first bottom face in opposite inclining directions, respectively, so that the groove gradually increases or gradually decreases from the side facing the base substrate to the side away from the base substrate in a direction perpendicular to an extending direction of the groove; or

the two inner side walls are parallel to each other, so that the groove has a same width from the side facing the base substrate to the side away from the base substrate in the direction perpendicular to the extending direction of the groove.

Illustratively, the light-transmitting bank pattern has a first top face at the side away from the base substrate, and the light-shielding bank pattern has a second top face at the side away from the base substrate; in the direction perpendicular to the base substrate, a thickness of the light-shielding bank pattern is smaller than a thickness of the light-transmitting bank pattern, so that there is a second step between the first top face and the second top face, and in the direction perpendicular to the base substrate, the groove is divided into a filled region which is filled with the light-shielding bank pattern and a recessed region not filled with the light-shielding bank pattern.

Illustratively, the leveling layer at least partially fills the recessed region.

Illustratively, in the direction perpendicular to the base substrate, at least a portion of the recessed region gradually expands from a side facing the base substrate to a side away from the base substrate; or at least a portion of the recessed region gradually converges from the side facing the base substrate to the side away from the base substrate; or at least a portion of the recessed region extends in a straight line from the side facing the base substrate to the side away from the base substrate.

In the direction perpendicular to the base substrate, at least a portion of the filled region gradually expands from the side facing the base substrate to the side away from the base substrate; or at least a portion of the filled region gradually converges from the side facing the base substrate to the side away from the base substrate; or at least a portion of the filled region extends in a straight line from the side facing the base substrate to the side away from the base substrate.

Illustratively, in a case where both the recessed region and the filled region gradually expand, an inclination angle of an inner side wall of the recessed region with respect to the light-emitting substrate is greater than or equal to an inclination angle of an inner side wall of a corresponding filled region with respect to the light-emitting substrate.

Illustratively, in the direction perpendicular to the base substrate, the light-transmitting bank pattern has a first bottom face at a side facing the base substrate and a first top face at a side away from the base substrate; at least a portion of the light-transmitting bank pattern includes two outer side walls in contact with the color conversion pattern which are opposite to each other in a direction parallel to the base substrate.

The two outer side walls incline with respect to the base substrate from the first top face to the first bottom face in opposite inclining directions; or

the two outer side walls are parallel to each other.

Illustratively, the color conversion pattern in each first opening comprises a third top face away from the base substrate, the third top face comprises a central region and a peripheral region located at a periphery of the central region, the peripheral region is closer to the separation bank than the central region; wherein in the direction perpendicular to the base substrate,

surfaces of the central region and the peripheral region are flush with each other; or

the central region protrudes with respect to the peripheral region in a direction away from the base substrate; or

the central region is recessed with respect to the peripheral region in a direction facing the base substrate.

Illustratively, inclination angles of the two outer side walls with respect to the base substrate range from 40 degrees to 80 degrees) (°).

Illustratively, the plurality of pixels includes a first pixel configured to display light of a first color, a second pixel configured to display light of a second color and a third pixel configured to display light of a third color; the light-emitting device is configured to emit the light of the third color.

The color conversion pattern includes: a first color conversion pattern, arranged in a second opening corresponding to the first pixel, wherein the first color conversion pattern is configured to enable an incident light of the third color to convert into the light of the first color and to emit the converted light;

a second color conversion pattern, arranged in a second opening corresponding to the second pixel, wherein the second color conversion pattern is configured to enable the incident light of the third color to convert into the light of the second color and to emit the converted light; and

a transmission pattern, arranged in a third opening corresponding to the third pixel, wherein the transmission pattern is configured to enable the incident light of the third color to pass therethrough.

Illustratively, the light-emitting device includes an OLED light-emitting device.

An embodiment of the present disclosure further provides a display device, including the display substrate as described above.

An embodiment of the present disclosure further provides a method for manufacturing a display substrate, the method including:

forming a light-emitting substrate, wherein the light-emitting substrate comprises a base substrate, a plurality of light-emitting devices, a plurality of switch elements and an encapsulation layer which are arranged on the base substrate, wherein the switch element is configured to drive the light-emitting device to emit light, the encapsulation layer encapsulates the light-emitting device, and at least one light-emitting device and at least one switch element are arranged in each pixel correspondingly;

forming a color conversion layer at a side of the encapsulation layer away from the base substrate, wherein the color conversion layer comprises a separation bank, a color conversion pattern and a leveling layer; the separation bank comprises a plurality of first portions extending in a first direction and a plurality of second portions extending in a second direction, the first direction intersects with the second direction and is parallel to the base substrate; the plurality of first portions and the plurality of second portions intersect with each other to define a plurality of first openings corresponding to the plurality of pixels; the separation bank is divided into a light-transmitting bank pattern and a light-shielding bank pattern, the light-transmitting bank pattern is provided with a groove arranged along at least one of the first direction and the second direction; the light-shielding bank pattern is filled in the groove, the color conversion pattern is arranged in the first opening, and a first step is between the color conversion pattern and the separation bank in a direction perpendicular to the base substrate; and the leveling layer at least fills the first step to form a flat surface at a side away from the base substrate; and

forming a color filtering layer at a side of the color conversion layer away from the base substrate, wherein the color filtering layer comprises a light-shielding pattern and a color filtering pattern, the light-shielding pattern defines second openings corresponding to the plurality of first openings, and the color filtering pattern is arranged in the second opening.

Illustratively, the forming a color conversion layer at the side of the encapsulation layer away from the base substrate, specifically includes:

forming a light-transmitting layer by using a light-transmitting material;

patterning the light-transmitting layer to form the groove and the first opening;

filling the groove with a light-shielding material to form the light-shielding bank pattern;

forming the color conversion layer within the first opening; and

filling the first opening with a leveling material to form the leveling layer.

Illustratively, the patterning the light-transmitting layer to form the groove and the first opening, specifically includes:

forming a photosensitive layer on the encapsulation layer; and

patterning the photosensitive layer by using a mask as a light-shielding mask to form the groove and the first opening.

Illustratively, the filling the groove with a light-shielding material to form the light-shielding bank pattern, specifically includes:

filling the light-shielding material into the groove; and

curing the light-shielding material to form the light-shielding bank pattern.

Various advantageous effect can be achieved by the embodiments of present disclosure.

In the display substrate, the manufacturing method thereof, and the display device provided by the embodiments of the present disclosure, the display substrate includes a light-emitting substrate, a color conversion layer and a filter layer stacked in sequence, in which the light-emitting substrate is used as a backlight source to emit light of a third color, the color conversion layer is disposed on a light-emitting side of the light-emitting substrate, and the color conversion layer includes a separation bank, a color conversion pattern and a leveling layer, in which a pattern of the separation bank can define a plurality of first openings corresponding to a plurality of pixels. The separation bank, on the one hand, serves as a bank into which the color conversion pattern is filled, and the separation bank, on the other hand, has a light-shielding property, which can avoid light mixing between color conversion patterns in different first openings and reduce color crosstalk. To prevent color mixing from occurring in the process of filling color conversion pattern, the thickness of the color conversion pattern is less than the thickness of the separation bank, in other words, the thickness of the separation bank is greater. in the above-mentioned solution, one part of the separation bank is made of a light-transmitting material, namely, forming the light-transmitting bank pattern, and the other part is made of a light-shielding material, namely, forming the light-shielding bank pattern. In this way, even if the thickness of the separation bank is relatively great (for example, greater than 10 microns), the curing of the separation bank can be ensured, and the phenomenon of incomplete curing can be reduced. The color conversion pattern is the first opening is configured to convert the light of the third color into another color for emission, or to directly transmit the light of the third color. To prevent color mixing from occurring in the process of filling the color conversion pattern, the thickness of the color conversion pattern is less than the thickness of the separation bank, so as to form a first step. The leveling layer can level the color conversion layer up to at least fill the step between the color conversion pattern and the separation bank to obtain a flat surface, which is favorable for subsequent preparations of film layers such as the color filtering layer. The color filtering layer may be configured to color filtering the light emitted from the color conversion pattern. For example, the color filtering layer may realize a basic color by absorbing a specific wavelength band of the incident light and selectively transmitting another specific wavelength band of the incident light therethrough. The display substrate, the manufacturing method thereof, and the display device provided by the embodiments of the present disclosure, can be applied to an On cell (on-cell) display substrate to reduce the color crosstalk and to improve the quality of the display product.

### BRIEF DESCRIPTION OF THE DRAWINGS

FIG. 1 shows a schematic plan view of a light-emitting substrate in a display substrate provided in an embodiment of the present disclosure;

FIG. 2 shows a schematic plan view of a color conversion layer in a display substrate provided in an embodiment of the present disclosure;

FIG. 3 shows a schematic plan view of a color filtering layer in a display substrate provided in an embodiment of the present disclosure;

FIG. 4 shows a schematic plan view of a display substrate provided in an embodiment of the present disclosure;

FIG. 5 shows a sectional view of a portion taken along a line D-D′ in FIG. 4; and

FIGS. 6 to 17 show various embodiments for a structure in a dashed box B in FIG. 5.

### DETAILED DESCRIPTION

To make the objects, technical solutions and advantages of embodiments of the present disclosure clearer, a detailed description for the embodiments of the present disclosure will be given by reference to the appended drawings. It is to be understood that the described embodiments are only some, but not all, of the embodiments of the disclosure. Based on the embodiments described in the present disclosure, all other embodiments obtained by a person of ordinary skill in the art without creative effort fall within the scope of the present disclosure.

Unless defined otherwise, technical or scientific terms used in this disclosure shall have the ordinary meaning as understood by one of ordinary skill in the art to which this disclosure belongs. The terms “first”, “second”, and the like as used herein do not denote any order, quantity, or importance, but rather are used to distinguish one element from another. Likewise, terms such as “a”, “an”, or “the” do not denote a limitation of quantity, but rather denote the presence of at least one of the referenced items. The terms “include” or “comprise”, and the like, means that the presence of an element or item preceding the word covers the presence of the element or item listed after the word and equivalents thereof, but does not exclude other elements or items. The terms “connect” or “couple” and the like are not limited to physical or mechanical connections, but may include electrical connections, whether direct or indirect. The terms “upper”, “lower”, “left”, “right” and the like are used only to indicate relative positional relationships that may change accordingly when the absolute position of the object being described changes.

Before describing the display substrate manufacturing method thereof, and the display device provided by the embodiments of the present disclosure in detail, a brief introduction the related art is given.

In the related art, for a quantum dot OLED panel or a fluorescent OLED panel, the photochromic QD (quantum dot) particles or a fluorescent material are excited by using a blue OLED as a backlight source, to obtain monochromatic red light and green light. Specifically, taking a QD-OLED (quantum dot panel) utilizing the on Cell (on-screen) process as an example, a color conversion layer and a color filtering layer may be sequentially stacked on a light-emitting side of a light-emitting substrate which is capable of emitting blue light. The color conversion layer may include a separation bank (Bank) which serves as a barrier and defines a plurality of openings corresponding to pixels, and the openings corresponding to different pixels may be filled with different QD particle materials or fluorescent materials, to obtain a color conversion pattern. The OLED material may be greatly affected by temperature, while the material of the separation bank should be subject to high temperature or UV light for curing fully when preparing the separation bank. The thickness of the QD material or the fluorescent material should be 10 microns or more in consideration of full absorption of OLED blue light and ensuring the conversion rate requirement for the color conversion pattern, while the thickness of the separation bank material should be larger than that of the QD material or the fluorescent material to prevent color crosstalk. As a result, there may be a limitation on the thickness of the separation bank. The inventors have found that if all the separation banks are made of light-shielding materials, and when the thickness of the separation bank is large, the UV light cannot penetrate through thick light-shielding materials curing due to the light-absorbing properties of the light-shielding materials, such that a full curing cannot be achieved. This may lead to the fact that the separation bank cannot be cured fully, which may in turn lead to a risk of collapse of the separation bank, thereby resulting in various defects in the product. In addition, since the thickness of the separation bank is greater than or equal to the thickness of the QD material or the fluorescent material, there may be a step therebetween.

To address the issues as mentioned above, embodiments of the present disclosure provide a display substrate, a manufacturing method thereof, and a display device, which can at least address the above-mentioned technical issues.

In an embodiment of the present disclosure, a display substrate is provided, having a plurality of pixels distributed in an array. The plurality of pixels may be defined to be arranged substantially in a matrix on a plane of the display substrate. As used herein, the term “pixel” refers to a single area defined by dividing a display area for displaying various colors from the viewpoint of a plane, and one pixel may represent a predetermined basic color. That is, one pixel may be the smallest unit for displaying color in the display substrate, and may be able to display color independently of other pixels.

In some exemplary embodiments, the plurality of pixels includes a first pixel PX1 for displaying light of a first color, a second pixel PX2 for displaying light of a second color, and a third pixel PX3 for displaying light of a third color.

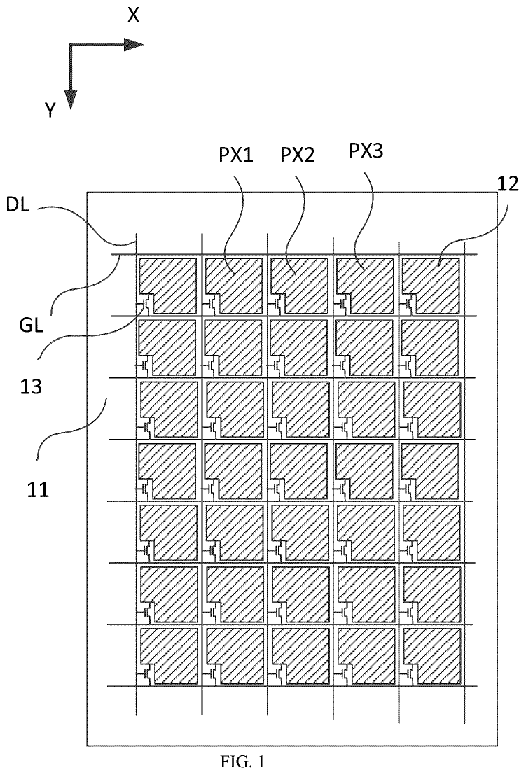

In some exemplary embodiments, as shown in FIG. 1, the first pixel PX1, the second pixel PX2, and the third pixel PX3 sequentially arranged in a first direction X may together form a pixel unit, the pixel unit may be repeatedly arranged in the first direction X. Each of the first pixel PX1, the second pixel PX2, and the third pixel PX3 may be repeatedly arranged in a second direction Y. In other words, the pixel units are distributed in an array in the first direction X and the second direction Y. For example, the first pixel PX1 may be a pixel for displaying the first color (namely, red) having a peak wavelength of about 610 nm to 650 nm; the second pixel PX2 adjacent to the first pixel PX1 in the first direction X may be a pixel for displaying the second color (namely, green) having a peak wavelength of about 530 nm to 570 nm; and the third pixel PX3 adjacent to the second pixel PX2 in the first direction X may be a pixel for displaying the third color (namely, blue) having a peak wavelength of about 430 nm to 470 nm.

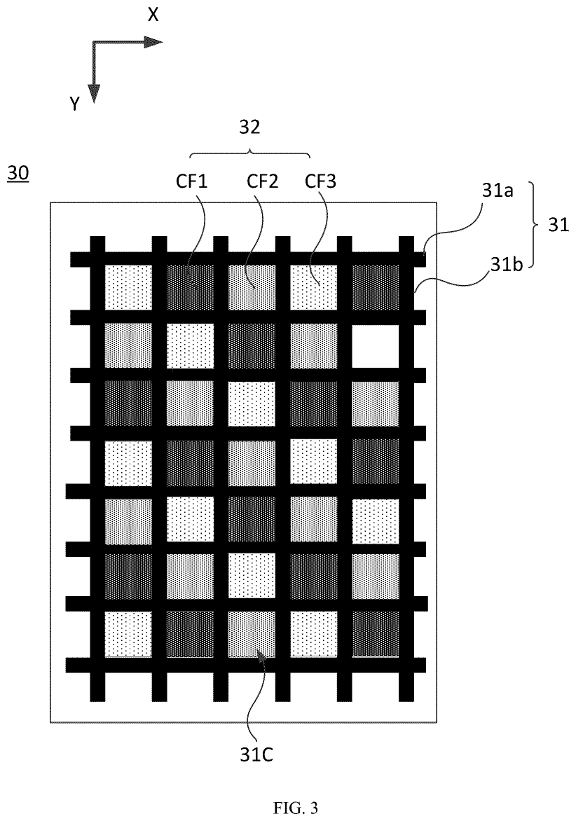

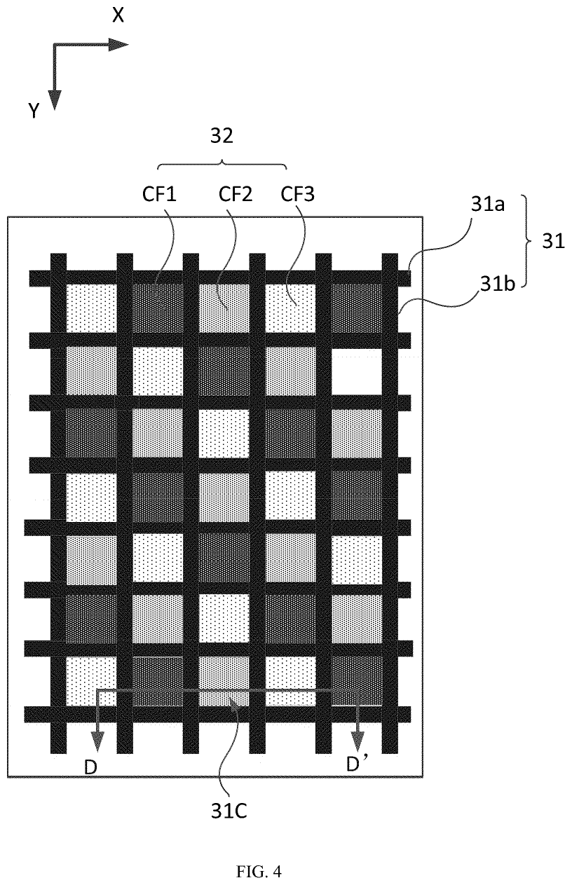

As shown in FIGS. 1 to 5, a display substrate provided by an embodiment of the present disclosure may include a light-emitting substrate (LS) 10, a color conversion layer 20, and a color filtering layer (CF) 30, which are sequentially stacked on one another.

The light-emitting substrate 10 may serve as a light source, which may include a base substrate (SUB) 11, a plurality of light-emitting devices (LDs) 12, a plurality of switch elements (T) 13, and an encapsulation layer 14 (TFE), the light-emitting devices 12, the switch elements 13 and the encapsulation layer 14 are arranged on the base substrate 11.

The base substrate 11 may be a transparent insulating substrate. For example, the base substrate 11 may be a base plate formed by a glass material, a quartz material, or a light-transmitting plastic material. In some exemplary embodiments, the base substrate 11 may be flexible and the display substrate may be a flexible display substrate.

The light-emitting device 12 may emit light. For example, the light-emitting device 12 may emit the light of the third color. For example, the light-emitting device 12 may be an OLED light-emitting device, which may include a cathode 121, an anode 122, and an organic light-emitting layer (EL) 123 located between the cathode 121 and the anode 122, and the organic light-emitting layer 123 may be a continuous thin film. Further, the organic light-emitting layer 123 may be a structure having stacked layers.

The switch element 13 is configured to drive the light-emitting device 12 to emit light, and in each pixel PX, at least one corresponding light-emitting device 12 and at least one corresponding switch element 13 are provided. The switch element 13 may transmit a driving signal to the light-emitting device 12 or may prevent the driving signal from transmitting to the light-emitting device 12.

In some exemplary embodiments, the switch element 13 may include: a gate electrode GE; an active layer AL arranged on the gate electrode GE; and a source electrode SE and a drain electrode DE spaced apart from each other on the active layer AL. The gate electrode GE served as a control terminal may be connected to a gate line GL to receive a gate driving signal, the source electrode SE served as an input terminal may be connected to a data line DL to receive a data driving signal, and the drain electrode DE served as an output terminal may be electrically connected to the anode 121 of the light-emitting device 12. The active layer AL may include amorphous silicon or polysilicon, or may be formed of an oxide semiconductor. The active layer AL serves as a channel of the switch element 13Q, and the channel may be turned on or off according to a voltage applied to the gate electrode GE. The gate electrode GE and the active layer AL may be insulated by an insulating film GI.

The encapsulation layer 14 (TFE) is used for encapsulating the light-emitting device 12 and may protect the organic light-emitting layer 123 from being subjected to water and oxygen, and the encapsulation layer 14 may be formed by laminating an organic material and an inorganic material. Illustratively, the encapsulation layer 14 may be a stack of silicon oxide, IJP organic material, and silicon nitride.

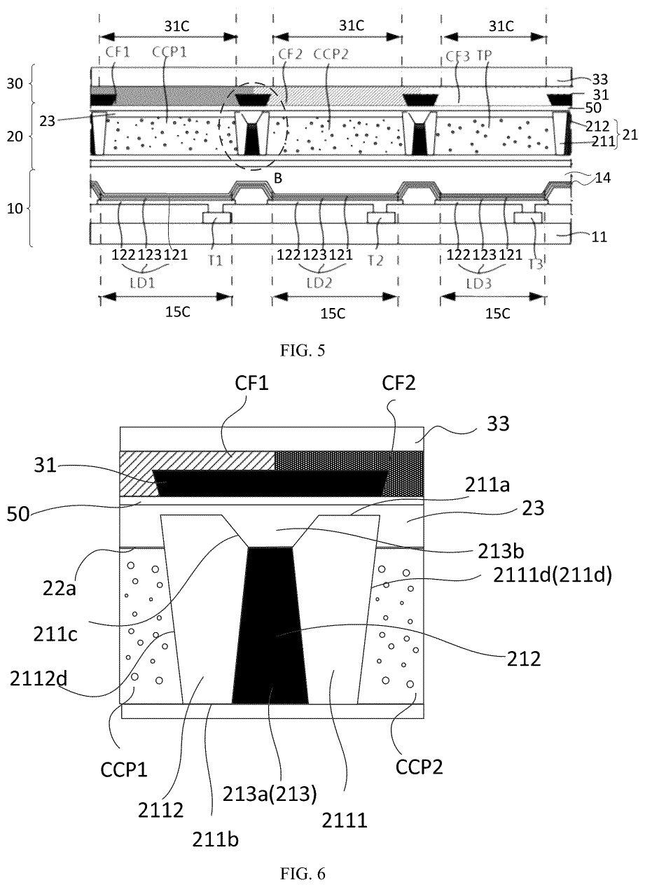

Furthermore, as shown in FIG. 5, the light-emitting substrate 10 further includes a pixel definition layer 15, where the pixel definition layer 15 defines third openings 15c corresponding to the plurality of pixels.

The color conversion layer 20 may be arranged at a side of the encapsulation layer 14 away from the base substrate 11. As shown in the figure, the color conversion layer 20 includes a separation bank (Bank) 21, a color conversion pattern (CCP) 22, and a leveling layer (LEVE) 23.

The separation bank 21 includes a plurality of first portions 21a extending in the first direction X, and a plurality of second portions 21b extending in the second direction Y, the first direction X intersects with the second direction Y and is parallel to the base substrate 11, and the plurality of first portions 21a intersect with the plurality of second portions 21b to define a plurality of first openings 21c corresponding to the plurality of pixels PX. That is, in a plan view parallel to the base substrate 11, the first portion 21a corresponds to a portion of the separation bank 21 extending in the first direction X, and the second portion 21b corresponds to a portion of the separation bank 21 extending in the second direction Y. The separation bank 21 may be provided along boundaries between two of the plurality of pixels PX, having a substantially lattice shape in a plan view, each of the first openings 21c is defined by intersections between adjacent two first portions 21a and adjacent two second portions 21b.

The color conversion pattern 22 is arranged in the first openings 21c, and the first openings 21c can facilitate the formation of the color conversion pattern 22. For example, when the color conversion pattern 22 is formed by means of ink-jet printing, the first openings 21c can facilitate the filling of QD (quantum dot) material or fluorescent material for conversion patterns 22 of different colors. The color conversion pattern 22 is located in the first opening 21c for emitting light of another color to which the light of the third color is converted or directly transmitting the light of the third color. That is, the color conversion pattern 22 may convert the color of the light transmitted therethrough into a different color from that of the light incident thereon. The light can be converted into a specific wavelength band after passing through the color conversion pattern 22. The material of the color conversion pattern 22 may be selected to be a material can convert or shift a peak wavelength of the incident light to a predetermined peak wavelength, i.e., a wavelength shift material. Illustratively, the wavelength shifting material may include a quantum dot material or a fluorescent material.

For example, the light-emitting device 12 of the light-emitting substrate 10 emits the light of the third color, and the color conversion pattern 22 may include: a first color conversion pattern CCP1, a second color conversion pattern CCP2 and a transmission pattern TP, where the first color conversion pattern CCP1 is arranged in a second opening corresponding to the first pixel PX1, and is configured to enable the incident light of the third color to convert into the light of the first color and to emit converted light; the second color conversion pattern CCP2 is arranged in a second opening corresponding to the second pixel PX2, and is configured to enable the incident light of the third color to convert into the light of the second color and to emit the converted light; the transmission pattern TP is arranged within a third opening corresponding to the third pixel PX3 and is configured to enable the incident light of the third color to pass through.

In an example in which the light of the third color is blue light, the light of the first color is red light and the light of the second color is green light, the wavelength shift materials for the first color conversion pattern CCP1 and the second color conversion pattern CCP2 may include the quantum dot material or the fluorescent material.

Specifically, the first color conversion pattern CCP1 and the second color conversion pattern CCP2 may be formed by mixing a white ink (resin material), QD nanoparticles of different sizes, and scattering particles. A doping ratio of QD nanoparticles to scattering particles is ≤60%.

Illustratively, the material of the first color conversion pattern CCP1 has QD nanoparticles whose particle size is between 3 nm and 7 nm, the material of the second color conversion pattern CCP2 has QD nanoparticles whose particle size is between 4 nm and 6 nm, and the material of the transmission pattern TP can directly transmit the light of the third color, and the material thereof can be selected as a mixture of a white ink and scattering particles.

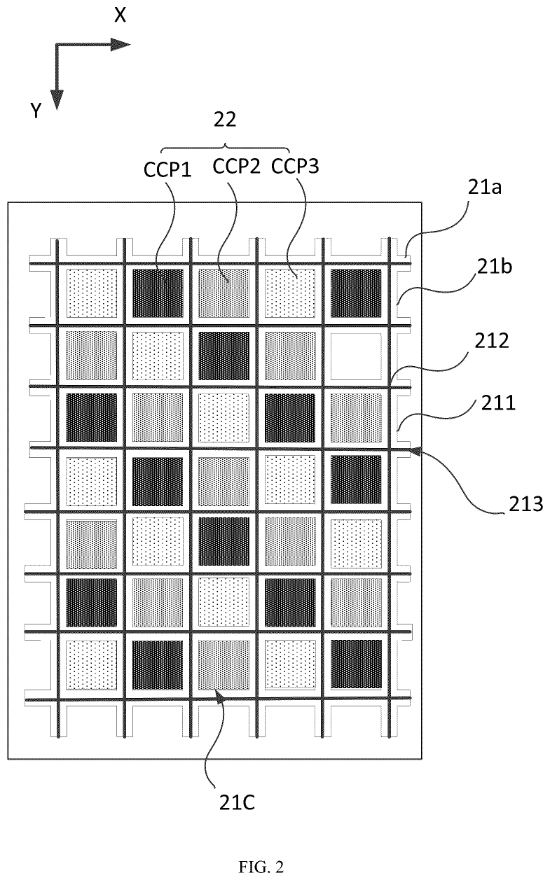

At least one of the first portion 21a and the second portion 21b includes a light-transmitting bank pattern 211 and a light-shielding bank pattern 212, the light-transmitting bank pattern 211 has a groove 213 provided along an extending direction of the at least one of the first portion 21a and the second portion 21b. As in shown in FIG. 2, for example, each of the first portion 21a and the second portion 21b may include the light-transmitting bank pattern 211 and the light-shielding bank pattern 212, and a groove 213 on the first portion 21a is arranged in the first direction X and a groove 213 on the second portion 21b is arranged in the second direction Y. As illustrated in the figure as an example, the light-transmitting bank pattern 211 on the first portion 21a is divided into a first light-transmitting bank 2111 and a second light-transmitting bank 2112 in a cross section taken along the second direction Y, the first light-transmitting bank 2111 and the second light-transmitting bank 2112 are spaced apart by the groove 213, and the light-shielding bank pattern 212 is filled in the groove 213.

Note that the light-transmitting bank pattern 211 may have a light transmission property. For example, the light-transmitting bank pattern 211 may have a light transmittance of at least about 90%, at least about 95%, at least about 98%, or at least about 99%. Since light having a wavelength of 365 nm (nanometer) to 436 nm is generally selected for exposure, the light-transmitting bank pattern 211 may be patterned by using an exposure process, and the light-transmitting bank pattern 211 can at least transmit the light having the wavelength of 365 nm to 436 nm, among others. It should be noted that the material of the light-transmitting bank pattern 211 is not limited as long as the material has a good light transmission property. For example, the material of the light-transmitting bank pattern 211 may be an organic material such as an epoxy resin, an acrylic resin, or an imide resin. The light-transmitting bank pattern 211 may be formed of an organic material, particularly a photosensitive organic material. The photosensitive organic material may be a positive or negative photosensitive material that cures when irradiated with light, but is not limited thereto. Also, the first light-transmitting bank 2111 and the second light-transmitting bank 2112 of the light-transmitting bank pattern 211 may be formed of the same material or of different materials.

The light-shielding bank pattern 212 may be formed of a light-shielding material capable of blocking light transmission. The light-shielding bank pattern 212 is a main portion in the separation bank 21 to function as a light blocking, and light transmission between color conversion patterns 22 in adjacent two first openings 21c may be blocked by the light-shielding bank pattern 212. The material of the light-shielding bank pattern 212 is not particularly limited, as long as a material capable of blocking light transmission is used. For example, the material of the light-shielding bank pattern 212 may be an organic material containing, for example, a black pigment or dye. In particular, the light-shielding bank pattern 212 may include a photosensitive organic material. The photosensitive organic material may be a positive or negative photosensitive material that cures when irradiated with light, but is not limited thereto. For example, an optical density of the light-shielding bank pattern 212 may be about 2.0/2 μm (micron) or more, about 3.0/2 μm or more, or about 4.0/2 μm or more. That is, the optical density of the light-shielding bank pattern 212 having a width of 2 μm may be about 2.0 or more, about 3.0 or more, or about 4.0 or more in the width direction.

Each light-shielding bank pattern 212 needs to have an enough thickness to block light from being transmitted among the first color conversion pattern CCP1, the second color conversion pattern CCP2 and the transmission pattern TP in adjacent two first openings 21c, i.e., to prevent light crosstalk. For example, the thickness of the light-shielding bank pattern 212 may be greater than or equal to 10 microns in a direction perpendicular to the base substrate 11.

Since the separation bank 21 serves as a bank for subsequently filling the color conversion pattern 22 on the one hand, and on the other hand the separation bank 21 has a light-shielding property to prevent light mixing between color conversion patterns 22 in different first openings 21c, thereby reducing color crosstalk; and in order to prevent color mixing from occurring during the filling process of the color conversion pattern 22, the thickness of the color conversion pattern 22 is less than the thickness of the separation bank 21, that is to say, the thickness of the separation bank 21 is greater. In the above-mentioned solution, a part of the separation bank 21 is made of a light-transmitting material, namely, forming the light-transmitting bank pattern 211. The other portion is made of a light-shielding material, i.e., forming the light-shielding bank pattern 212. In this way, even if the thickness of the separation bank 21 is large (for example, greater than 10 microns), its curing effect can be ensured, and incomplete curing can be reduced.

In some embodiments, as shown in FIGS. 5 and 6, in the direction perpendicular to the base substrate 11, a thickness of the color conversion pattern 22 may be smaller than the thickness of the separation bank 21, so that the color mixing may be prevented in the process of filling the color conversion pattern 22. Since the thickness of the color conversion pattern 22 is less than the thickness of the separation bank 21, a first step may exist therebetween, the leveling layer 23 can level up the color conversion layer 20, to fill at least a mismatch between the color conversion pattern 22 and the separation bank 21 to obtain a flat surface. This may facilitate a preparation of subsequent film layers such as the color filtering layer 30.

Specifically, the leveling layer 23 needs to have a leveling property to form the flat surface. For example, the leveling layer 23 may be selected to be an organic resin-based material, specifically, a white ink (resin material) which is not doped with scattering particles may be selected, but is not limited thereto.

The color filtering layer 30 is arranged at a side of the color conversion layer 20 away from the base substrate 11. The color filtering layer 30 includes a light-shielding pattern (BM) 31, a color filtering pattern (CF) 32, and a planarization layer 33. The light-shielding pattern (BM) 31 defines second openings 31c corresponding to the plurality of first openings 21c, and the color filtering pattern (CF) 32 is arranged in the second opening 31c.

Illustratively, the color filtering layer 30 may include a first color filtering pattern CF1 corresponding to the first pixel PX1, a second color filtering pattern CF2 corresponding to the second pixel PX2, and a third color filtering pattern CF3 corresponding to the third pixel PX3. The first color filtering pattern CF1 may transmit the light of the first color, the second color filtering pattern CF2 may transmit the light of the second color, and the third color filtering pattern CF3 may transmit the light of the third color.

The light-shielding pattern 31 serves as a light shielding member, i.e., a black matrix, which can be used to define the position of the color filtering pattern 32, and can be formed by using a material such as a silicone resin.

Exemplarily, the light-shielding pattern 31 includes a plurality of third portions 31a extending in the first direction X, and a plurality of fourth portions 31b extending in the second direction Y. The plurality of third portions 31a and the plurality of fourth portions 31b intersect with each other to define a plurality of second openings 31c, where a maximum width of the third portion 31a in the second direction Y is greater than or equal to a maximum width of a corresponding first portion 21a in the second direction Y; and a maximum width of the fourth portion 31b in the first direction X is greater than or equal to a maximum width of a corresponding second portion 21b in the first direction X.

In some exemplary embodiments, as shown in FIG. 5, the display substrate in embodiments of the present disclosure may further include at least one buffer layer 50 (CAP1), the at least one buffer layer 50 is located on the flat surface of the leveling layer 23, and the color filtering layer 30 is located at a side of the buffer layer 50 away from the color conversion layer 20.

The buffer layer 50 may be used to protect internal device structure from being etched by water and oxygen and then damaged, and may also be used as a flexible bonding buffer between the backlight part (including the light-emitting substrate 10 and the color conversion layer 20) and the display part (including the color filtering layer 30). The buffer layer 50 may be formed of an inorganic material.

In some embodiments of the present disclosure that are not illustrated, at least one buffer layer 50 may conformally cover a side of the color conversion pattern 22 and a side of the separation bank 21 that are away from the base substrate 11, to form an uneven area formed by the first step, and the leveling layer 23 is located at a side of the buffer layer 50 away from the base substrate 11 and fills at least the uneven area to form the flat surface.

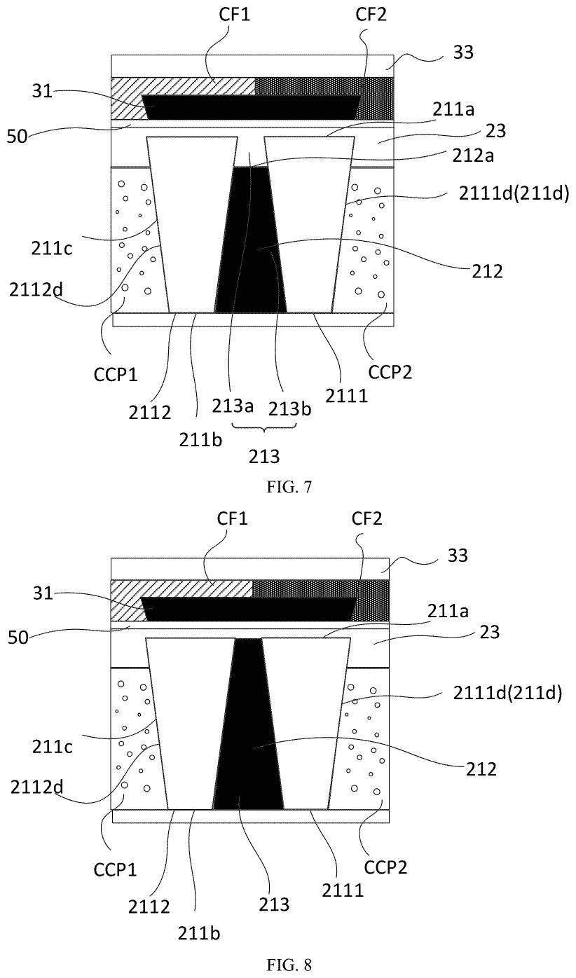

Furthermore, in some exemplary embodiments, as shown in FIGS. 8, 9 and 11, in the direction perpendicular to the base substrate 11, the light-transmitting bank pattern 211 has a first top face 211a at a side away from the base substrate 11 and the light-blocking bank pattern 212 has a second top face 212a at a side away from the base substrate 11; the light-shielding bank pattern 212 and the light-transmitting bank pattern 211 have the same thickness in the direction perpendicular to the base substrate 11 so that the first top face 211a is flush with the second top face 212a.

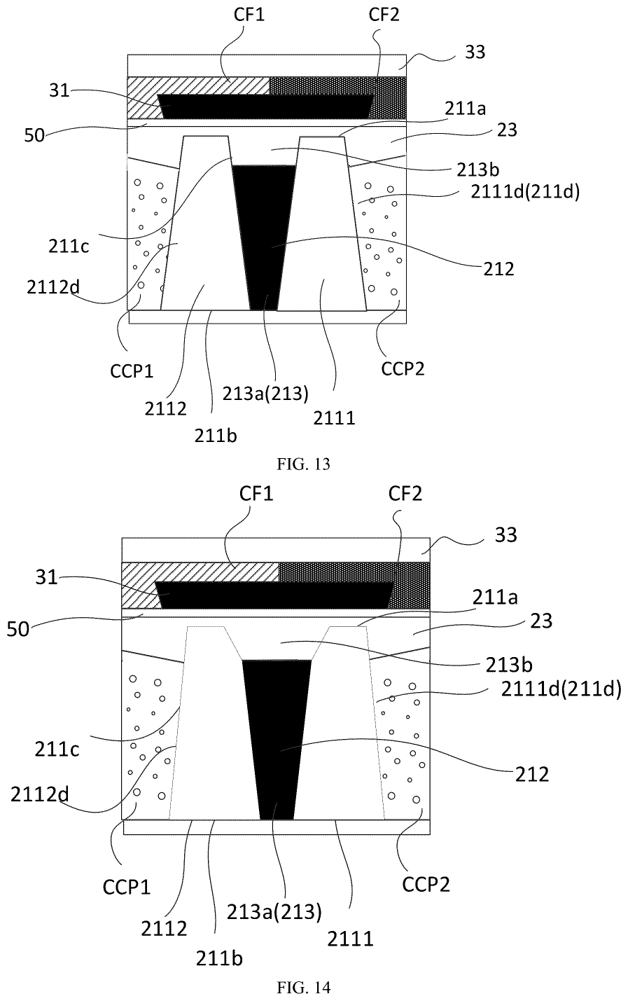

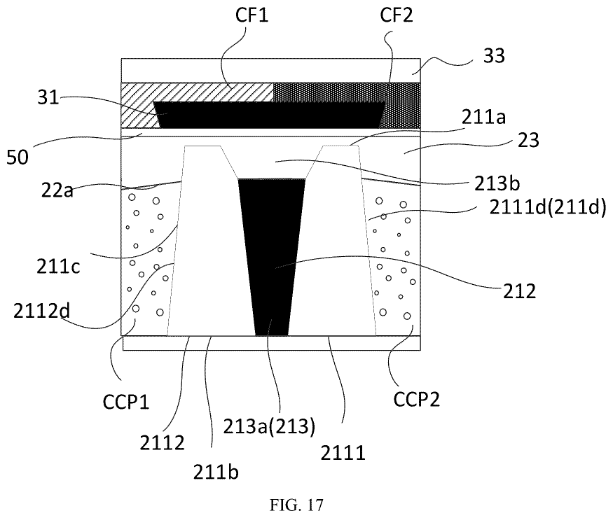

In some other embodiments, as shown in FIGS. 6, 7, 9-10, 13-14, and 16-17, the thickness of the light-shielding bank pattern 212 is smaller than the thickness of the light-transmitting bank pattern 211 in the direction perpendicular to the base substrate 11, so that there is a second step between the first top face 211a and the second top face 212a. In the direction perpendicular to the base substrate 11, the groove 213 is divided into a filled region 213a filled with the light-shielding bank pattern 212 and a recessed region 213b not filled with the light-shielding bank pattern 212, and the leveling layer 23 may be at least partially filled in the recessed region 213b. With this arrangement, since the thickness of the light-transmitting bank pattern is greater than the thickness of the light-shielding bank pattern 212, that is to say, the light-transmitting bank pattern will be higher than the light-shielding bank pattern 212 so as to form the recessed region 213b, the recessed region 213b can serve as a fault-tolerant storage area for the ink of the color conversion pattern 22 during ink-jet printing. In other words, when problems such as the accuracy error of the ink-jet printing causes some deviations in the position for filling ink of the color conversion pattern 22 corresponding to a certain color, the ink will enter the recessed region 213b without mixing into ink of the color conversion pattern 22 of another color, so as to avoid the occurrence of color mixing phenomenon. In addition, due to the presence of the recessed region 213b, the recessed region 213b can release a stress, such that the device may be applicable in a screen bending display product, and the depth of the recessed region 213b may be adjusted to adjust the stress relief effect.

When the thickness of the light-shielding bank pattern 212 and the thickness of the light-transmitting bank pattern 211 are the same in the direction perpendicular to the base substrate 11, the separation bank 21 may include, but is not limited to, the following implementations.

As shown in FIG. 11, in an embodiment, in the direction perpendicular to the base substrate 11, the light-transmitting bank pattern 211 has a first bottom face 211b at a side facing the base substrate 11; the light-transmitting bank pattern 211 includes two opposite inner side walls 211c in contact with the light-shielding bank pattern 212; the two inner side walls 211c incline with respect to the base substrate 11 from the first top face 211a to the first bottom face 211b in opposite inclining directions, respectively, such that the groove 213 gradually increases from the side facing the base substrate 11 to the side away from the base substrate 11 in a direction perpendicular to a direction in which the groove 213 extends. For example, as shown in FIG. 11, in a cross-section taken along the direction perpendicular to the direction in which the groove 213 extends, the shape of the light-transmitting bank pattern 211 is substantially a trapezoidal shape having a narrow bottom and a wide top in the illustrated direction.

As shown in FIG. 8, in another embodiment, in the direction perpendicular to the base substrate 11, the light-transmitting bank pattern 211 has a first bottom face 211b at a side facing the base substrate 11; the light-transmitting bank pattern 211 includes two opposite inner side walls 211c in contact with the light-shielding bank pattern 212; the two inner side walls 211c incline with respect to the base substrate 11 from the first top face 211a to the first bottom face 211b in opposite inclining directions, respectively, such that the groove 213 gradually decreases from the side facing the base substrate 11 to the side away from the base substrate 11 in a direction perpendicular to a direction in which the groove 213 extends. For example, as shown in FIG. 8, in a cross-section taken along the direction perpendicular to the direction in which the groove 213 extends, the shape of the light-transmitting bank pattern 211 is substantially a trapezoidal shape having a narrow top and a wide bottom in the illustrated direction.

In another embodiment, in the direction perpendicular to the base substrate 11, the light-transmitting bank pattern 211 has a first bottom face 211b at a side facing the base substrate 11; the light-transmitting bank pattern 211 includes two opposite inner side walls 211c in contact with the light-shielding bank pattern 212; the two inner side walls 211c are parallel to each other so that the width of the groove 213 from the side facing the base substrate 11 to the side away from the base substrate 11 in a direction perpendicular to a direction in which the groove 213 extends is equal. For example, in a cross-section taken along the direction perpendicular to the direction in which the groove 213 extends, the shape of the light-transmitting bank pattern 211 is substantially a rectangular shape having uniform widths at both top and bottom.

When the thickness of the light-shielding bank pattern 212 is smaller than the thickness of the light-transmitting bank pattern 211, the separation bank 21 may include the following implementations.

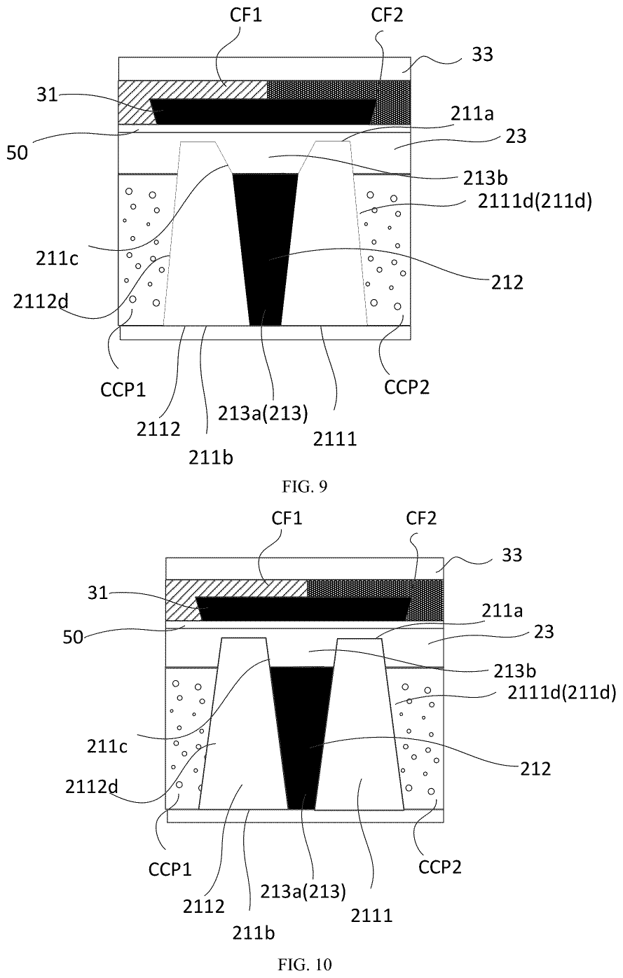

Implementations of the recessed region 213b may include: in the direction perpendicular to the base substrate 11, at least a portion of the recessed region 213b gradually expands from a side facing the base substrate 11 to a side away from the base substrate 11 (as shown in FIG. 9); or at least a portion of the recessed region 213b gradually converges from the side facing the base substrate 11 to the side away from the base substrate 11 (as shown in FIG. 7); or at least a portion of the recessed region 213b passes through in a straight line from the side facing the base substrate 11 to the side far from the base substrate 11;

Embodiments of the filled region 213a may include: in a direction perpendicular to the base substrate 11, at least a portion of the filled region 213a gradually expands from a side facing the base substrate 11 to a side away from the base substrate 11 (as shown in FIG. 9); or at least a portion of the filled region 213a gradually converges from the side facing the base substrate 11 to the side far from the base substrate 11 (as shown in FIG. 7); alternatively, at least a part of the filled region 213a extends in a straight line from the side facing the base substrate 11 to the side away from the base substrate 11.

It should be understood that FIGS. 6 to 17 illustrate only several embodiments for specific structures, but specific embodiments of the separation bank 21 is not limited thereto, which may include all embodiments obtained by performing permutation and combination on various embodiments of the recessed region 213b and various embodiments of the filled region 213a.

Note that, in some embodiments, as shown in FIG. 6, when both the recessed region 213b and the filled region 213a gradually expand, an inclination angle of the inner side wall 211c of the recessed region 213b with respect to the light-emitting substrate 10 is greater than or equal to an inclination angle of the inner side wall 211c corresponding to the filled region 213a with respect to the light-emitting substrate 10. That is, as shown in FIG. 6, a cut angle design is applied to the inner side wall 211c of the recessed region 213b, such that an expansion angle of the inner side wall 211c is larger than that of the filled region 213a, which is favorable for receiving ink when ink-jet printing the color conversion pattern 22.

In some embodiments, as shown in FIGS. 6 to 17, at least a portion of the light-transmitting bank pattern 211 includes two outer side walls 211d which are in contact with the color conversion pattern 22 and are opposite to each other in the direction parallel to the base substrate 11. That is, as shown in FIGS. 6 to 17, in a cross section taken along a direction perpendicular to an extending direction of the groove 213, the light-transmitting bank pattern 211 is divided into a first light-transmitting bank 2111 and a second light-transmitting bank 2112, where the first light-transmitting bank 2111 includes a first outer side wall 2111d for contacting the color conversion pattern 22 and the second light-transmitting bank 2112 includes a second outer side wall 2112d for contacting the color conversion pattern 22, the first outer side wall 2111d and the second outer side wall 2112d are inclined with respect to the base substrate 11.

For example, in an embodiment, as shown in the figures, in the direction perpendicular to the base substrate 11, the light-transmitting bank pattern 211 has a first bottom face 211b at a side facing the base substrate 11 and a first top face 211a at a side away from the base substrate 11, and the first outer side walls 211d are inclined downward (as shown in FIGS. 9 to 17) or upward (as shown in FIGS. 6 to 8) with respect to the base substrate 11 from the first top face 211a to the first bottom face 211b in opposite inclined directions.

In some other embodiments that are not illustrated, the two outer side walls 211d may also be parallel to each other.

Note that the inclining directions of the two outer side walls 211d and the inclining directions of the two inner side walls 211c may be substantially opposite.

In addition, the two outer side walls 211d are in direct contact with the color conversion pattern 22. Since wettability between different ink materials and the separation bank 21 may be different, when the contact angles between the outer side walls 211d and the color conversion patterns 22 are different, and when the ink materials of the color conversion patterns 22 are different, the ink surface tensions are different thereby forming color conversion patterns 22 with different appearances. Example are given hereinafter.

In some embodiments, as shown in FIGS. 6-11, the color conversion pattern 22 within each first opening 21c includes a third top face 22a away from the base substrate 11, the third top face 22a includes a central region and a peripheral region locate at a periphery of the central region, the peripheral region is closer to the separation bank 21 when comparing with the central region. In the direction perpendicular to the base substrate 11, surfaces of the central region and the peripheral region are flush with each other. That is, the third top face 22a of the color conversion pattern 22 is a planar face.

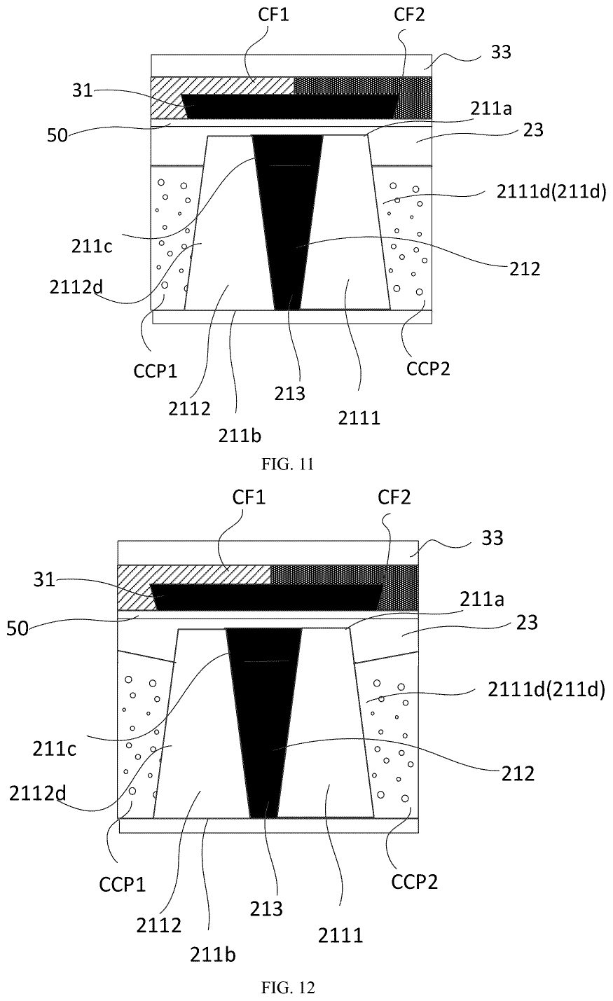

In some other embodiments, as shown in FIGS. 12-14, the central region protrudes with respect to the peripheral region in the direction away from the base substrate 11. That is, the color conversion pattern 22 formed after curing has an appearance in which the middle part projects to be higher than the periphery.

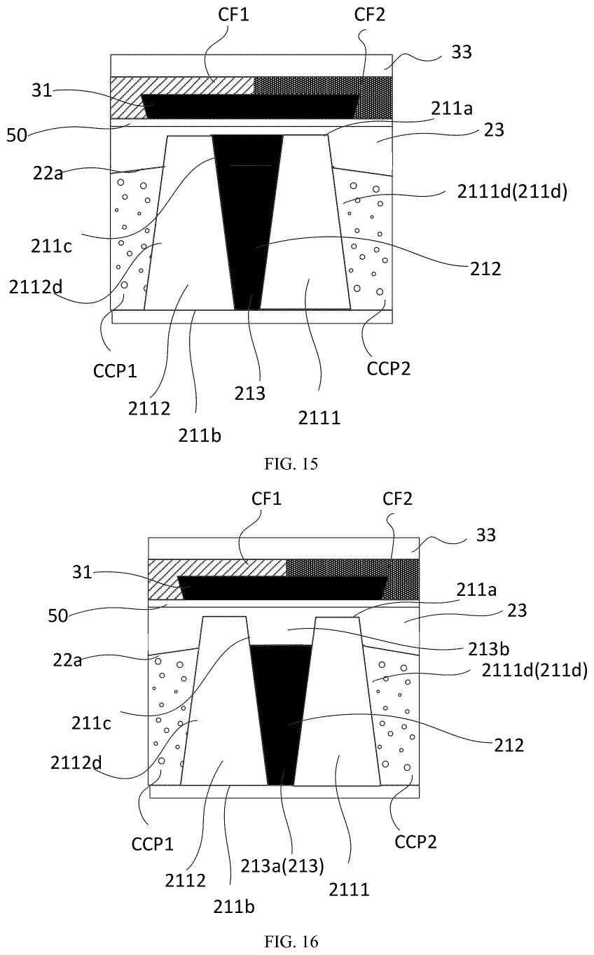

In some other embodiments, as shown in FIGS. 15-17, the central region is recessed with respect to the peripheral region in the direction facing the base substrate 11. That is, the color conversion pattern 22 formed after curing has an appearance in which the middle part recess to be lower than the periphery.

In practical applications, the contact angle between the ink and the outer side wall 211d of the light-transmitting bank pattern 211 and the materials for the ink and the outer side wall 211d of the light-transmitting bank pattern 211 may be adjusted to obtain a desired color conversion pattern 22 appearance. Illustratively, the inclination angle of the two outer side walls 211d with respect to the base substrate 11 may range from 40 to 80 degrees.

In addition, it should be noted that FIGS. 6 to 17 illustrate only a few embodiments, and in practical applications, the embodiments of the separation bank 21 are not limited thereto, and may include all embodiments in which permutation and combination are performed on the implementations respectively for the light-transmitting bank pattern, the light-shielding bank pattern 212, the groove 213 and the like as described above.

In addition, the inclining directions of the outer side wall 211d and the inner side wall 211c may be opposite or the same. Here, the opposite inclining direction means that, for example, the outer side wall 211d forms an obtuse angle with respect to the base substrate 11, and the inner side wall 211c forms an acute angle with respect to the base substrate 11. The same inclining direction means that, for example, the outer side wall 211d forms an acute angle with respect to the base substrate 11, and the inner side wall 211c forms an acute angle with respect to the base substrate 11.

In addition, an embodiment of the present disclosure further provides a display device, including the display substrate provided by the embodiments of the present disclosure. The display apparatus may include various display devices such as a cell phone, a computer, a television, etc.

In addition, an embodiment of the present disclosure further provides a method for manufacturing the display substrate in the embodiments of the present disclosure, the method including the steps of S01 to S03.
Step S01: forming the light-emitting substrate 10, where the light-emitting substrate 10 includes a substrate 11, and a plurality of light-emitting devices 12, a plurality of switch elements 13 and an encapsulation layer 14 arranged on the base substrate 11, the switch element 13 is configured to drive the light-emitting device 12 to emit light, the encapsulation layer 14 encapsulates the light-emitting device 12, and at least one light-emitting device 12 and at least one switch element 13 are arranged in each pixel PX correspondingly.
Step S02: forming a color conversion layer 20 at a side of the encapsulation layer 14 away from the base substrate 11, where the color conversion layer 20 includes a separation bank 21, a color conversion pattern 22 and a leveling layer 23, the separation bank 21 includes a plurality of first portions 21a extending in a first direction X and a plurality of second portions 21b extending in a second direction Y, the first direction X intersects with the second direction Y and the first direction X is parallel to the base substrate 11, the plurality of first portions 21a and the plurality of second portions 21b intersect with each other to define a plurality of first openings 21c corresponding to the plurality of pixels PX, the separation bank 21 is divided into a light-transmitting bank pattern 211 and a light-shielding bank pattern 212, the light-transmitting bank pattern 211 is provided with a groove 213 arranged along at least one of the first direction X and the second direction Y, the light-shielding bank pattern 212 is filled in the groove 213, and the color conversion pattern 22 is arranged in the first openings 21c; and a first step is forming between the color conversion pattern 22 and the separation bank 21 in a direction perpendicular to the base substrate 11, and the leveling layer 23 at least fills the first step to form a flat surface at a side away from the base substrate 11.
Step S03: forming a color filtering layer 30 at a side of the color conversion layer 20 away from the base substrate 11, where the color filtering layer 30 includes a light-shielding pattern 31 and a color filtering pattern 32, the light-shielding pattern 31 defines second openings 31c corresponding to the plurality of first openings 21c, the color filtering pattern 32 is arranged in the second opening 31c.

Illustratively, in the step S01, the base substrate 11 may be a transparent insulating substrate. For example, the base substrate 11 may be a base plate formed of a glass material, a quartz material, or a light-transmitting plastic material. In some exemplary embodiments, the base substrate 11 may be flexible and the display substrate may be a flexible display substrate. The light-emitting device 12 may emit light, for example, the light-emitting device 12 may emit light of a third color, for example, the light-emitting device 12 (LD) may be an OLED light-emitting device 12, i.e., a light-emitting diode device that converts electrical energy into optical energy, which may include a cathode 121, an anode 122, and an organic light-emitting layer 123 (EL) located between the cathode 121 and the anode 122. The organic light-emitting layer 123 may be a continuous thin film. Further, the organic light-emitting layer 123 may have a structure of stacked layers. The switch element 13 is configured to drive the light-emitting device 12 to emit light, and in each pixel PX, at least one light-emitting device 12 and at least one switch element 13 are correspondingly provided, and the switch element 13 may transmit a driving signal to the light-emitting device 12 or may prevent the driving signal from transmitting to the light-emitting device 12. In some exemplary embodiments, the switch element 13Q may include: a gate electrode GE; an active layer AL arranged on the gate electrode GE; and a source electrode SE and a drain electrode DE spaced apart from each other on the active layer AL. The gate electrode GE served as a control terminal may be connected to a gate line GL to receive a gate driving signal, the source electrode SE served as an input terminal may be connected to a data line DL to receive a data driving signal, and the drain electrode DE served as an output terminal may be electrically connected to a pixel electrode PE. The active layer AL may include amorphous silicon or polysilicon, or may be formed of an oxide semiconductor. The active layer AL serves as a channel of the switch element 13Q, and the channel can be turned on or off according to a voltage applied to the gate electrode GE. The gate electrode GE and the active layer AL can be insulated by an insulating film GI; the encapsulation layer 14 (14) encapsulates the light-emitting device 12 and may serve to protect the organic light-emitting layer 123 from being subjected to water and oxygen. The encapsulation layer 14 may be formed of a stack of organic and inorganic materials. For example, the encapsulation layer 14 may be formed of a stack of silicon oxide, IJP organic material and silicon nitride.

Illustratively, the step S02 specifically includes following steps.
Step S021: forming a light-transmitting layer by using a light-transmitting material, and patterning the light-transmitting layer to form the groove 213 and the first opening 21c.
Step S022: filling a light-shielding material in the groove 213 to form the light-shielding bank pattern 212.
Step S023: forming the color conversion layer 20 in the first opening 21c.
Step S024: filling a leveling material in the first opening 21c to form the leveling layer 23.

Illustratively, the step S021 specifically includes following steps.
Step S0211: forming a photosensitive layer on the encapsulation layer 14.

The light transmitting material may have light transmitting property, for example, may have a light transmittance of at least about 90%, at least about 95%, at least about 98%, or at least about 99%. The light-transmitting material is not limited as long as the material has a good light transmittance. For example, the light-transmitting material may be an organic material such as an epoxy resin, an acrylic resin, or an imide resin. The light-transmitting material may be an organic material, particularly a photosensitive organic material. The photosensitive organic material may be a positive or negative photosensitive material that cures when irradiated with light, but is not limited thereto. Also, the first separation bank 21 and the second separation bank 21 of the light-transmitting bank pattern 211 may be formed of the same material or different materials.
Step S0212: patterning the photosensitive layer by using a mask as a light-shielding mask to form the groove 213 and the first opening 21c.

The patterning process may include, but is not limited to, a photolithography process. For example, light is applied to the light-transmitting layer with a mask as an exposure mask, and the light-transmitting bank pattern 211 is formed by applying a developer. Taking a case where the light-transmitting material includes a negative photosensitive material as an example, a portion of the light-transmitting layer to which the light is applied through an aperture of the mask may be cured, and the remaining portion of the light-transmitting layer may be removed by the developer, thereby obtaining the light-transmitting bank pattern 211 including a pattern of the groove 213 and the first opening 21c.

Illustratively, step S022 specifically includes following steps.
Step S0221: filling the light-shielding material into the groove 213.

Step S0222: curing the light-shielding material to form the light-shielding bank pattern 212.

In the above-described solution, the curing of the light-shielding material may be facilitated by applying light from a side of a surface facing away from the base substrate 11 (i.e., the top surface in the drawing) to partially cure the light-shielding material. In some exemplary embodiments, the stiffness and thickness after curing may be controlled by controlling the intensity of light applied to the light-shielding material and a duration during which the light applied to the light-shielding material thereby controlling the depth of exposure.

In addition, the step S023 may specifically include: forming the color conversion pattern 22 in the first opening 21c by ink-jet printing. For example, taking a case where the light of the third color is blue light, the light of the first color is red light, and the light of the second color is green light as an example, inks for ink-jet printing the first color conversion pattern CCP1 and the second color conversion pattern CCP2 may include quantum dot material. Specifically, the first color conversion pattern CCP1 and the second color conversion pattern CCP2 may be formed by mixing a white ink (resin material), QD nanoparticles of different sizes, and scattering particles. A doping ratio of QD nanoparticles to scattering particles is less than or equal to 60%. Illustratively, QD nanoparticles in the material of the first color conversion pattern CCP1 have a particle size between 3 nm and 7 nm, QD nanoparticles in the material of the second color conversion pattern CCP2 have a particle size between 4 nm and 6 nm, and the material of the transmission pattern TP can directly transmit the light of the third color, and the material of the transmission pattern TP may be selected as a mixture of a white ink and scattering particles.

The following points need to be explained:
(1) The drawings only relate to the structures to which the embodiments of the present disclosure involve, and other structures may refer to general designs.
(2) In the drawings used to describe embodiments of the present disclosure, the thickness of layers or regions is exaggerated or reduced for clarity, i.e., the drawings are not to scale. It will be understood that when an element such as a layer, film, region or substrate is referred to as being “on” or “under” another element, it can be “directly on” or “directly under” the other element or intervening elements may be present.
(3) Without conflict, embodiments of the present disclosure and features of the embodiments may be combined with each other to provide new embodiments.

The foregoing is directed to specific embodiments of the present disclosure, but the scope of the disclosure is not limited thereto, and the scope of the disclosure is set forth in the appended claims.

1. A display substrate, having a plurality of pixels distributed in an array, wherein the display substrate comprises:
a light-emitting substrate, comprising a base substrate, a plurality of light-emitting devices, a plurality of switch elements and an encapsulation layer which are arranged on the base substrate, wherein the switch element is configured to drive the light-emitting device to emit light, the encapsulation layer encapsulates the light-emitting device, and at least one light-emitting device and at least one switch element are arranged in each pixel correspondingly;
a color conversion layer, arranged at a side of the encapsulation layer away from the base substrate, wherein the color conversion layer comprises a separation bank, a color conversion pattern and a leveling layer; the separation bank comprises a plurality of first portions extending in a first direction and a plurality of second portions extending in a second direction, the first direction intersects with the second direction and is parallel to the base substrate; the plurality of first portions and the plurality of second portions intersect with each other to define a plurality of first openings corresponding to the plurality of pixels; at least one of the first portion and the second portion comprises a light-transmitting bank pattern and a light-shielding bank pattern; the light-transmitting bank pattern is provided with a groove arranged in a direction in which the at least one of the first portion and the second portion extends, the light-shielding bank pattern is filled in the groove; the color conversion pattern is arranged in the first opening, and a first step is between the color conversion pattern and the separation bank in a direction perpendicular to the base substrate, and the leveling layer at least partially fills the first opening to fill the first step and form a flat surface at a side away from the base substrate; and
a color filtering layer, arranged at a side of the color conversion layer away from the base substrate, wherein the color filtering layer comprises a light-shielding pattern and a color filtering pattern, the light-shielding pattern defines a plurality of second openings corresponding to the plurality of first openings, and the color filtering pattern is arranged in the second opening.

2. The display substrate according to claim 1, wherein the display substrate further comprises at least one buffer layer;
wherein the at least one buffer layer is located on the flat surface of the leveling layer, and the color filtering layer is located at a side of the buffer layer away from the color conversion layer; and/or
the at least one buffer layer conformally covers a side of the color conversion pattern and the separation bank away from the base substrate, to form an uneven area formed by the first step, and the leveling layer is located at a side of the buffer layer away from the base substrate and at least fills the uneven area to form the flat surface.

3. The display substrate according to claim 1, wherein the color conversion pattern comprises a quantum dot material or a fluorescent material.

4. The display substrate according to claim 1, wherein the light-shielding pattern includes a plurality of third portions extending in the first direction and a plurality of fourth portions extending in the second direction, the plurality of third portions and the plurality of fourth portions intersect with each other to define the plurality of second openings; and
wherein a maximum width of the third portion in the second direction is greater than or equal to a maximum width of a corresponding first portion in the second direction; and a maximum width of the fourth portion in the first direction is greater than or equal to a maximum width of a corresponding second portion in the first direction.

5. The display substrate according to claim 1, wherein in the direction perpendicular to the base substrate, the light-transmitting bank pattern has a first top face at the side away from the base substrate, and the light-shielding bank pattern has a second top face at the side away from the base substrate; the light-shielding bank pattern and the light-transmitting bank pattern have the same thickness in the direction perpendicular to the base substrate so that the first top face is flush with the second top face.

6. The display substrate according to claim 5, wherein in the direction perpendicular to the base substrate, the light-transmitting bank pattern has a first bottom face at a side facing the base substrate; the light-transmitting bank pattern comprises two opposite inner side walls in contact with the light-shielding bank pattern; and
the two inner side walls incline with respect to the base substrate from the first top face to the first bottom face in opposite inclining directions, respectively, so that the groove gradually increases or gradually decreases from the side facing the base substrate to the side away from the base substrate in a direction perpendicular to an extending direction of the groove; or
the two inner side walls are parallel to each other, so that the groove has a same width from the side facing the base substrate to the side away from the base substrate in the direction perpendicular to the extending direction of the groove.

7. The display substrate according to claim 1, wherein the light-transmitting bank pattern has a first top face at the side away from the base substrate, and the light-shielding bank pattern has a second top face at the side away from the base substrate; in the direction perpendicular to the base substrate, a thickness of the light-shielding bank pattern is smaller than a thickness of the light-transmitting bank pattern, so that there is a second step between the first top face and the second top face, and in the direction perpendicular to the base substrate, the groove is divided into a filled region which is filled with the light-shielding bank pattern and a recessed region not filled with the light-shielding bank pattern.

8. The display substrate according to claim 7, wherein the leveling layer at least partially fills the recessed region.

9. The display substrate according to claim 7, wherein in the direction perpendicular to the base substrate, at least a portion of the recessed region gradually expands from a side facing the base substrate to a side away from the base substrate; or at least a portion of the recessed region gradually converges from the side facing the base substrate to the side away from the base substrate;
or at least a portion of the recessed region extends in a straight line from the side facing the base substrate to the side away from the base substrate; and
in the direction perpendicular to the base substrate, at least a portion of the filled region gradually expands from the side facing the base substrate to the side away from the base substrate; or at least a portion of the filled region gradually converges from the side facing the base substrate to the side away from the base substrate; or at least a portion of the filled region extends in a straight line from the side facing the base substrate to the side away from the base substrate.

10. The display substrate according to claim 9, wherein in a case where both the recessed region and the filled region gradually expand, an inclination angle of an inner side wall of the recessed region with respect to the light-emitting substrate is greater than or equal to an inclination angle of an inner side wall of a corresponding filled region with respect to the light-emitting substrate.

11. The display substrate according to claim 7, wherein at least a portion of the light-transmitting bank pattern comprises two outer side walls in contact with the color conversion pattern which are opposite to each other in a direction parallel to the base substrate; in the direction perpendicular to the base substrate, the light-transmitting bank pattern has a first bottom face at the side facing the base substrate; the two outer side walls incline with respect to the base substrate from the first top face to the first bottom face in opposite inclining directions, respectively, or the two outer side walls are parallel to each other.

12. The display substrate according to claim 11, wherein the color conversion pattern in each first opening comprises a third top face away from the base substrate, the third top face comprises a central region and a peripheral region located at a periphery of the central region, the peripheral region is closer to the separation bank than the central region; wherein in the direction perpendicular to the base substrate,
surfaces of the central region and the peripheral region are flush with each other; or
the central region protrudes with respect to the peripheral region in a direction away from the base substrate; or
the central region is recessed with respect to the peripheral region in a direction facing the base substrate.

13. The display substrate according to claim 11, wherein inclination angles of the two outer side walls with respect to the base substrate ranges from 40 degrees to 80 degrees.

14. The display substrate according to claim 1, wherein the plurality of pixels includes a first pixel configured to display light of a first color, a second pixel configured to display light of a second color and a third pixel configured to display light of a third color; the light-emitting device is configured to emit the light of the third color; the color conversion pattern comprises:
a first color conversion pattern, arranged in a second opening corresponding to the first pixel, wherein the first color conversion pattern is configured to enable an incident light of the third color to convert into the light of the first color and to emit the converted light;
a second color conversion pattern, arranged in a second opening corresponding to the second pixel, wherein the second color conversion pattern is configured to enable the incident light of the third color to convert into the light of the second color and to emit the converted light; and
a transmission pattern, arranged in a third opening corresponding to the third pixel, wherein the transmission pattern is configured to enable the incident light of the third color to transmit therethrough.

15. The display substrate according to claim 1, wherein the light-emitting device includes an OLED light-emitting device.

16. A display device, comprising a display substrate, the display substrate having a plurality of pixels distributed in an array, wherein the display substrate comprises:
a light-emitting substrate, comprising a base substrate, a plurality of light-emitting devices, a plurality of switch elements and an encapsulation layer which are arranged on the base substrate, wherein the switch element is configured to drive the light-emitting device to emit light, the encapsulation layer encapsulates the light-emitting device, and at least one light-emitting device and at least one switch element are arranged in each pixel correspondingly;
a color conversion layer, arranged at a side of the encapsulation layer away from the base substrate, wherein the color conversion layer comprises a separation bank, a color conversion pattern and a leveling layer; the separation bank comprises a plurality of first portions extending in a first direction and a plurality of second portions extending in a second direction, the first direction intersects with the second direction and is parallel to the base substrate; the plurality of first portions and the plurality of second portions intersect with each other to define a plurality of first openings corresponding to the plurality of pixels; at least one of the first portion and the second portion comprises a light-transmitting bank pattern and a light-shielding bank pattern; the light-transmitting bank pattern is provided with a groove arranged in a direction in which the at least one of the first portion and the second portion extends, the light-shielding bank pattern is filled in the groove; the color conversion pattern is arranged in the first opening, and a first step is between the color conversion pattern and the separation bank in a direction perpendicular to the base substrate, and the leveling layer at least partially fills the first opening to fill the first step and form a flat surface at a side away from the base substrate; and
a color filtering layer, arranged at a side of the color conversion layer away from the base substrate, wherein the color filtering layer comprises a light-shielding pattern and a color filtering pattern, the light-shielding pattern defines a plurality of second openings corresponding to the plurality of first openings, and the color filtering pattern is arranged in the second opening.

17. A method for manufacturing a display substrate, the method comprising:
forming a light-emitting substrate, wherein the light-emitting substrate comprises a base substrate, a plurality of light-emitting devices, a plurality of switch elements and an encapsulation layer which are arranged on the base substrate, wherein the switch element is configured to drive the light-emitting device to emit light, the encapsulation layer encapsulates the light-emitting device, and at least one light-emitting device and at least one switch element are arranged in each pixel correspondingly;
forming a color conversion layer at a side of the encapsulation layer away from the base substrate, wherein the color conversion layer comprises a separation bank, a color conversion pattern and a leveling layer; the separation bank comprises a plurality of first portions extending in a first direction and a plurality of second portions extending in a second direction, the first direction intersects with the second direction and parallel to the base substrate; the plurality of first portions and the plurality of second portions intersect with each other to define a plurality of first openings corresponding to the plurality of pixels; the separation bank is divided into a light-transmitting bank pattern and a light-shielding bank pattern, the light-transmitting bank pattern is provided with a groove arranged along at least one of the first direction and the second direction; the light-shielding bank pattern is filled in the groove, the color conversion pattern is arranged in the first opening, and a first step is between the color conversion patter and the separation bank in a direction perpendicular to the base substrate; and the leveling layer at least fills the first step to form a flat surface at a side away from the base substrate; and
forming a color filtering layer at a side of the color conversion layer away from the base substrate, wherein the color filtering layer comprises a light-shielding pattern and a color filtering pattern, the light-shielding pattern defines second openings corresponding to the plurality of first openings, and the color filtering pattern is arranged in the second opening.

18. The method according to claim 17, wherein the forming a color conversion layer at a side of the encapsulation layer away from the base substrate comprises:
forming a light-transmitting layer by using a light-transmitting material;
patterning the light-transmitting layer to form the groove and the first opening;
filling the groove with a light-shielding material to form the light-shielding bank pattern;
forming the color conversion layer within the first opening; and
filling the first opening with a leveling material to form the leveling layer.

19. The method according to claim 18, wherein the patterning the light-transmitting layer to form the groove and the first opening comprises:
forming a photosensitive layer on the encapsulation layer; and
patterning the photosensitive layer by using a mask as a light-shielding mask to form the groove and the first opening.

20. The method according to claim 19, wherein the filling the groove with a light-shielding material to form the light-shielding bank pattern comprises:
filling the light-shielding material into the groove; and
curing the light-shielding material to form the light-shielding bank pattern.
